(19) United States
(12) Patent Application Publication
(10) Pub. No.: US 2015/0059833 A1
(43) Pub. Date: Mar. 5, 2015

(54) PHOTOELECTRIC PANEL ASSEMBLY

(71) Applicant: Samsung SDI Co., Ltd., Yongin-si (KR)

(72) Inventors: Jung-Yup YANG, Yongin-si (KR); Seok-Joon YOON, Yongin-si (KR); Dong-Hun NO, Yongin-si (KR); Yeon-Il KANG, Yongin-si (KR); Min-Gu KIM, Yongin-si (KR); Kwang-Sik JEON, Yongin-si (KR)

(73) Assignee: Samsung SDI Co., Ltd., Yongin-si (KR)

(21) Appl. No.: 14/284,957

(22) Filed: May 22, 2014

Related U.S. Application Data
(60) Provisional application No. 61/870,978, filed on Aug. 28, 2013.

(51) Int. Cl. H01L 31/042

(52) U.S. Cl. CPC H01L 31/0422
USPC 136/251

(57) ABSTRACT

A photoelectric panel assembly includes a photoelectric panel, a support rail coupled to a rear surface of the photoelectric panel, the support rail including a base portion parallel to and spaced apart from the photoelectric panel, flange portions parallel to and adhered to the photoelectric panel, slope portions between the base portion and respective ones of the flange portions, and rounded portions between the base portion and the slope portions and between the slope portions and the flange portions.

### CROSS-REFERENCE TO RELATED APPLICATION

The present application claims priority under 35 U.S.C. §119 to U.S. Provisional Application No. 61/870,978, filed on Aug. 28, 2013, and entitled: “Photoelectric Panel Assembly,” which is incorporated herein by reference in its entirety.

### BACKGROUND

1. Field

One or more embodiments relate to a photoelectric panel assembly.

2. Description of the Related Art

Recently, development of clean energy is accelerating due to depletion of energy resources and environmental pollution. Since a sunlight generation system using a solar cell, which generates clean energy, directly converts sunlight to electricity, sunlight is expected to be a source of new energy.

A solar cell panel may have an approximately flat shape, and a frame may be adhered to a rear surface of the solar cell panel for installation. Also, the solar cell panel may be fixed on a support by using the frame.

### SUMMARY

Embodiments are directed to a photoelectric panel assembly including a photoelectric panel, a support rail coupled to a rear surface of the photoelectric panel, the support rail including a base portion parallel to and spaced apart from the photoelectric panel, flange portions parallel to and adhered to the photoelectric panel slope portions between the base portion and respective ones of the flange portions, and rounded portions between the base portion and the slope portions and between the slope portions and the flange portions.

A bending angle between the base portion and each of the slope portions and between each of the slope portions and each of the flange portions may be between about 80° and about 130°.

A bending angle between the base portion and each of the slope portions and between each of the slope portions and each of the flange portions may be between about 95° and about 105°.

A bending angle between the base portion and each of the slope portions and between each of the slope portions and each of the flange portions may be about 100°.

A ratio of a radius of curvature of the rounded portions between the base portion and the slope portions and between the slope portions and the flange portions and a length of the support rail, the length of the support rail being a distance between outer ends of the flange portions, may be greater than 0 (%) and less than or equal to 2.728 (%).

A ratio of a radius of curvature of the rounded portions between the base portion and the slope portions and between the slope portions and the flange portions and a length of the support rail, the length of the support rail being a distance between outer ends of the flange portions, may be greater than or equal to 4.364 (%) mm and less than or equal to 9.819 (%) mm.

The photoelectric panel assembly may further include an adhesion layer between the flange portions and the photoelectric panel.

The support rail may extend in a first direction and may further include a mount rail extending in a second direction different from the first direction. The mount rail may be connected to the base portion of the support rail.

The mount rail may be connected to the base portion of the support rail through a bracket that is attached to a surface of the base portion facing away from the photoelectric panel.

The support rail may be elongated in a first direction.

A length of the support rail in the first direction may be less than a length of the photoelectric panel in the first direction.

A length of the support rail in the first direction may be less than half a length of the photoelectric panel in the first direction.

Embodiments are also directed to a photoelectric panel assembly including a photoelectric panel, and a plurality of support rails coupled to a rear surface of the photoelectric panel. Each support rail includes a base portion parallel to and spaced apart from the photoelectric panel, flange portions parallel to and adhered to the photoelectric panel, and slope portions, between the base portion and respective ones of the flange portions. Each of the support rails is elongated in a first direction, a length of each of the support rails in the first direction being less than half a length of the photoelectric panel in the first direction. The support rails are spaced apart from each other in the first direction and in a second direction perpendicular to the first direction so as to be symmetrically arranged with respect to a center of the photoelectric panel.

The plurality of support rails may be four in number, each of the support rails being centered in a respective quadrant of the photoelectric panel.

With respect to each of the support rails, a bending angle between the base portion and each of the slope portions and between each of the slope portions and each of the flange portions may be between about 80° and about 130°.

A bending angle between the base portion and each of the slope portions, and between each of the slope portions, and each of the flange portions may be between about 95° and about 105°.

A bending angle between the base portion and each of the slope portions, and between each of the slope portions, and each of the flange portions may be about 100°.

Each of the support rails may include rounded portions between the base portion and the slope portions and between the slope portions and the flange portions.

A ratio of a radius of curvature of the rounded portions between the base portion and the slope portions and between the slope portions and the flange portions and a length of the support rail, the length of the support rail being a distance between outer ends of the flange portions, may be greater than 0 mm and less than or equal to 2.728 (%).

A ratio of a radius of curvature of the rounded portions between the base portion and the slope portions and between the slope portions and the flange portions and a length of the support rail, the length of the support rail being a distance between outer ends of the flange portions, may be greater than or equal to 4.364 (%) mm and less than or equal to 9.819 (%) mm.

### BRIEF DESCRIPTION OF THE DRAWINGS

Features will become apparent to those of skill in the art by describing in detail exemplary embodiments with reference to the attached drawings in which:

FIG. 1 illustrates an exploded perspective view of a photoelectric panel assembly;

FIG. 2 illustrates a view showing an arrangement of a support rail in the photoelectric panel assembly of FIG. 1;

FIG. 3 illustrates a view showing coupling between a photoelectric panel and the support rail in the photoelectric panel assembly of FIG. 1;

FIG. 4 illustrates a perspective view of the support rail of FIG. 1;

FIG. 5 illustrates s a cross-sectional view taken along a line V-V of FIG. 4;

FIGS. 6 and 7 illustrate views showing various shapes of the support rail according to a bending angle of the support rail;

FIG. 8 illustrates a graph showing a safety factor according to a bending angle of the support rail;

FIG. 9 illustrates a view showing a cross-sectional shape of a support rail according to a bending angle of the support rail;

FIG. 10 illustrates a view showing a cross-sectional shape of a support rail, according to another embodiment;

FIG. 11 illustrates a graph showing a safety factor of the support rail according to a radius of curvature of a round portion;

FIG. 12 illustrates a graph showing a safety factor of the support rail according to a ratio of a radius of curvature of a round portion to a length of the support rail;

FIG. 13 illustrates a view showing a cross-sectional shape of a support rail according to a radius of curvature of the support rail;

FIG. 14 illustrates a view for describing a case when a sheet metal is excessively bent while forming a support rail;

FIG. 15A illustrates a view showing a cross-sectional shape of a support rail according to a comparative example;

FIG. 15B illustrates a view showing a deformed state of the support rail of FIG. 15A; and

FIG. 16 illustrates a view showing a deformed state of a support rail, according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. In the drawing figures, the dimensions of layers and regions may be exaggerated for clarity of illustration. Like reference numerals refer to like elements throughout.

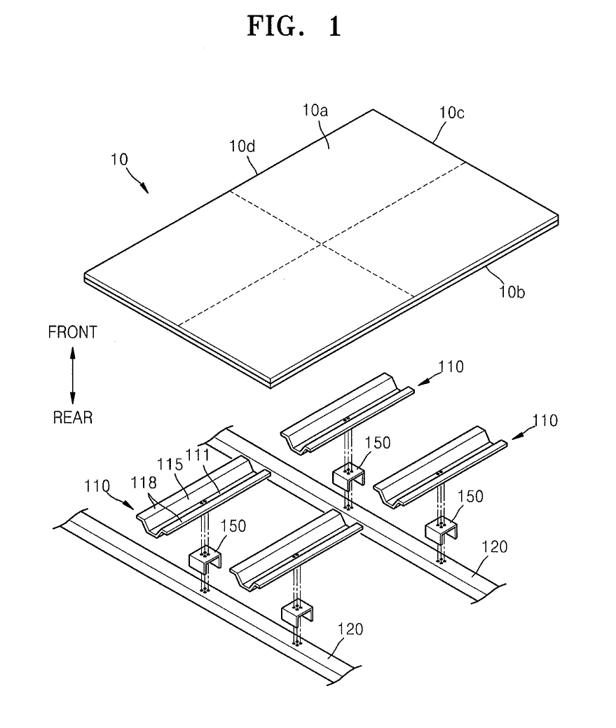

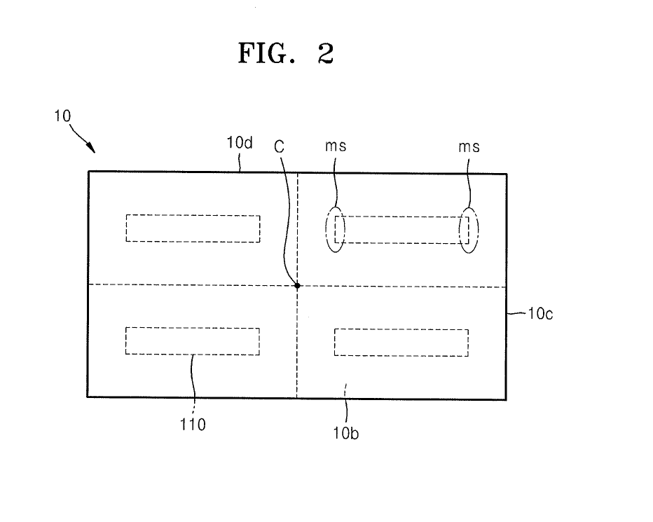

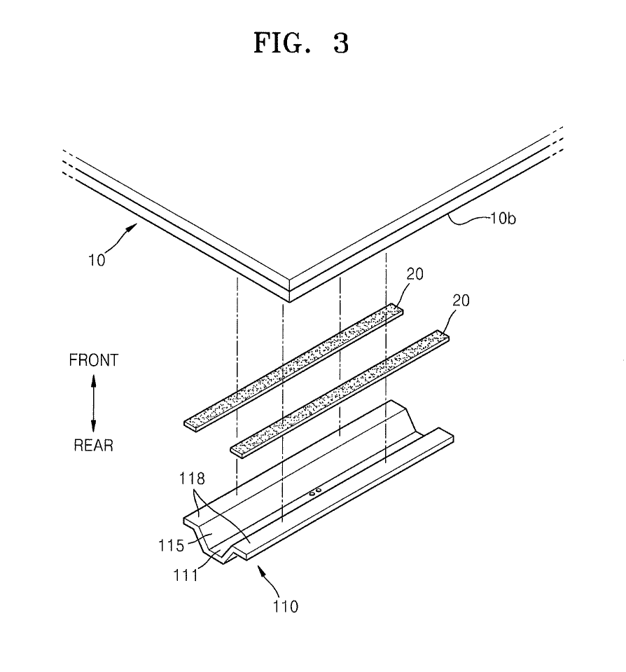

FIG. 1 illustrates an exploded perspective view of a photoelectric panel assembly. FIG. 2 illustrates a view showing an arrangement of a support rail 110 in the photoelectric panel assembly of FIG. 1. FIG. 3 illustrates a view showing coupling between a photoelectric panel 10 and the support rail 110 in the photoelectric panel assembly of FIG. 1.

Referring to FIGS. 1 through 3, the photoelectric panel assembly includes the photoelectric panel 10 and the support rail 110 for supporting the photoelectric panel 10.

The photoelectric panel 10 may perform photoelectric transformation to output electric energy by using an incident light from a sun as an input. For example, the photoelectric panel 10 may include a solar cell module including a plurality of photoelectric cells (not shown).

A front surface 10a and a rear surface 10b of the photoelectric panel 10 may respectively be a light-receiving surface and a non-light-receiving surface of the photoelectric panel 10. For example, the front surface 10a of the photoelectric panel 10 may form a light-receiving surface for receiving the incident light from the sun, and the rear surface 10b of the photoelectric panel 10 may form a non-light-receiving surface opposite to the light-receiving surface. The photoelectric panel 10 may be tilted from a horizontal surface of the ground at a predetermined angle so as to receive a maximum amount of solar radiation from the sum.

The photoelectric panel 10 may have an overall rectangular flat panel shape. For example, the photoelectric panel 10 may have a rectangular shape having a pair of long sides 10d and a pair of short sides 10c.

The support rail 110 may be assembled at the rear surface 10b of the photoelectric panel 10. The support rail 110 may support the rear surface 10b of the photoelectric panel 10. The support rail 110 may provide structural rigidity by being coupled to the rear surface 10b of the photoelectric panel 10. For example, the support rail 110 may provide a structure for fixing the photoelectric panel 10 on a mount rail 120 supporting the photoelectric panel 10.

The support rail 110 may be fixed on the mount panel 120 through a base portion 111. For example, the support rail 110 may be fixed on the mount rail 120 through a bracket 150 provided on a rear surface of the base portion 111.

The support rail 110 may be formed of a steel material, such as galvanized steel, or a nonferrous metal material, such as aluminum or zinc. In other implementations, the support rail 110 may be formed of any one of various metal materials or a polymer material, such as plastic.

The support rail 110 may be a slender member extending along one direction. A plurality of the support rails 110 may be arranged at the rear surface 10b of the photoelectric panel 10. For example, as shown in FIG. 2, the support rails 110 may extend in parallel to the long sides 10d of the photoelectric panel 10, and may be spaced apart from each other at top, bottom, left, and right locations at the rear surface 10b of the photoelectric panel 10. The support rails 110 may be disposed at the top, bottom, left, and right locations that are symmetrical such that a weight of the photoelectric panel 10 is approximately uniformly distributed. For example, the four support rails 110 may be disposed at symmetrical locations based on a center C of the photoelectric panel 10, and may be balanced so that a stress is not concentrated to one support rail 110. In the current embodiment, the number of support rails 110 is four, and the support rails 110 are disposed at regular intervals.

The support rail 110 may provide structural rigidity sufficient to stably support the photoelectric panel 10. The support rail 110 supports the weight of the photoelectric panel 10, and may support the weight of the photoelectric panel 10 at a location that is tilted with respect to the horizontal surface of the ground. Shapes and locations of the support rails 110 may be determined by considering not only the weight of the photoelectric panel 10, but also a mechanical stress applied to the photoelectric panel 10 by environmental factors, such as wind, heat, snow, or rain.

As shown in FIG. 3, the support rail 110 may be coupled to the rear surface 10b of the photoelectric panel 10 through an adhesion layer 20 disposed between the support rail 110 and the rear surface 10b of the photoelectric panel 10. For example, a flange portion 118 of the support rail 110 may be adhered to the rear surface 10b of the photoelectric panel 10 via the adhesion layer 20, such as a double-sided tape or a bonding sealant.

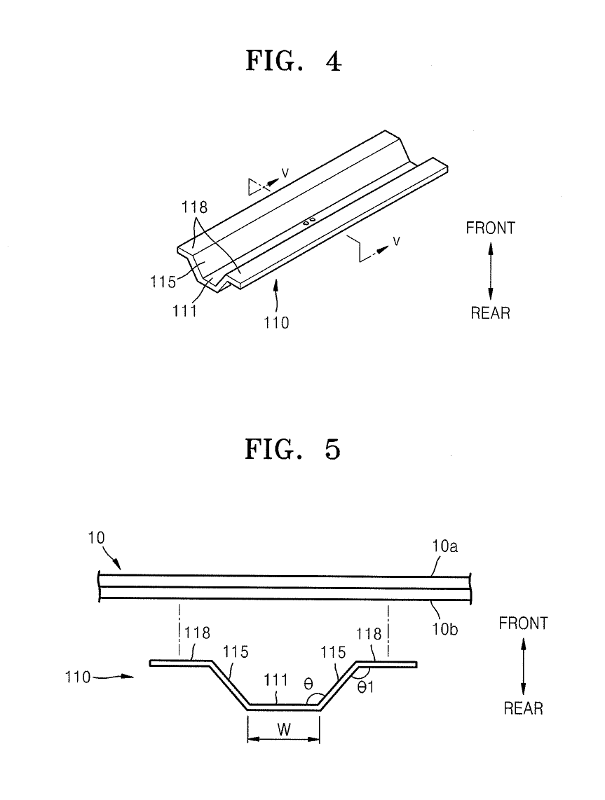

FIG. 4 illustrates a perspective view of the support rail 110 of FIG. 1. FIG. 5 illustrates a cross-sectional view taken along a line V-V of FIG. 4.

Referring to FIGS. 4 and 5, a cross-sectional shape of the support rail 110 may have a concave groove to have suitable rigidity with respect to bending moment. In other implementations, the support rail 110 may be variously deformed whether to be suppressed from being bent, or for convenient installation.

The support rail 110 may have the flange portion 118 bent to face and align with the photoelectric panel 10. The flange portion 118 may provide surface-contact with the rear surface 10b of the photoelectric panel 10, and may support the photoelectric panel 10 over a wide area. For example, the flange portion 118 may be formed at the rear surface 10b of the photoelectric panel 10. An adhesion between the support rail 110 and the photoelectric panel 10 may be mediated by disposing the adhesion layer 20 of FIG. 3 between the flange portion 118 and the photoelectric panel 10.

The support rail 110 may include the base portion 111 at the center, the flange portion 118 protruding towards the photoelectric panel 10 at two sides of the base portion 111, and a slope portion 115 that is inclined to connect front and rear stepped portions between the base portion 111 and the flange portion 118.

For example, the base portion 111 and the flange portion 118 may extend in parallel to each other. The base portion 111 may be formed at the rear towards the mount rail 120 of FIG. 1 and the flange portion 118 may be formed at the front towards the photoelectric panel 10. The support rail 110 may be fixed on the mount rail 120 through the base portion 111, and coupled to the rear surface 10b of the photoelectric panel 10 through the flange portion 118.

The base portion 111 and the flange portion 118 may be respectively disposed at the rear and front towards the mount rail 120 and the photoelectric panel 10, and the slope portion 115 may be disposed between the base portion 111 and the flange portion 118 to mutually connect them. For example, the slope portion 115 may have an inclined shape to connect the front and rear stepped portions between the base portion 111 and the flange portion 1118. The base portion 111 and the flange portion 118 may be disposed in parallel to face the photoelectric panel 10, and the slope portion 115 may extend in a diagonal direction of the photoelectric panel 10.

Referring to FIG. 5, the base portion 111 and the slope portion 115 may contact each other while having a bending angle θ. The bending angle θ between the base portion 111 and the slope portion 115 may be an important design variable in designing the shape of the support rail 110.

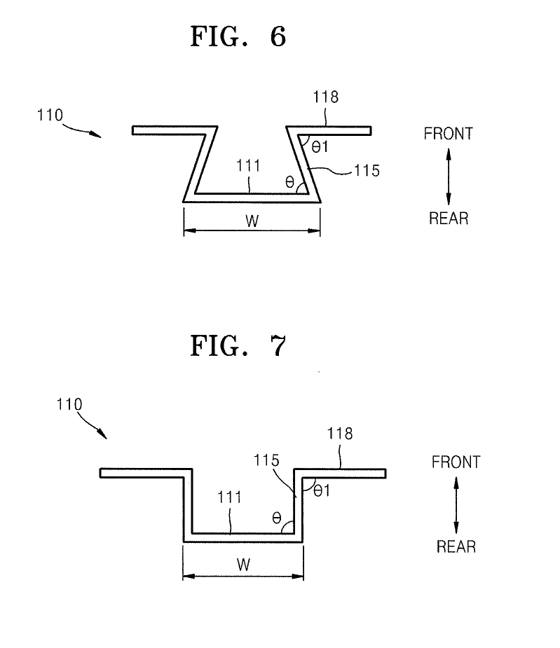

For example, the support rail 110 may have different shapes as shown in FIGS. 5 through 7 according to the bending angle θ of the support rail 110. According to the bending angle θ of the support rail 110, the slope portion 115 may extend more outwardly than a width W of the base portion 111 (FIG. 5), may extend more inwardly than the width W of the base portion 111 (FIG. 6), or extend evenly along the width W of the base portion 111 (FIG. 7). In FIG. 5, the bending angle θ is larger than 90° and in FIG. 6, the bending angle θ is smaller than 90°. In FIG. 7, the bending angle θ is 90°.

The bending angle θ of the support rail 110 may be variously designed in order to distribute a stress caused not only by the weight of the photoelectric panel 10, but also by a wind load or a snow load applied to the photoelectric panel 10 by environment factors, such as wind, snow, or rain, and to prevent the support rail 110 from being damaged by stress concentration.

The bending angle θ of the support rail 110 may define an angle between the base portion 111 and the slope portion 115, while the bending angle θ1 may define an angle between the slope portion 115 and the flange portion 118. As shown in FIGS. 5 through 7, the base portion 111 and the flange portion 118 may extend parallel to each other. Accordingly, the base portion 111 and the flange portion 118 may contact the slope portion 115 with the same bending angle (θ=θ1).

Hereinafter, for convenience, the term “bending angle θ of the support rail 110” may be used to simultaneously denote the angle θ between the base portion 111 and the slope portion 115, and the angle θ1 between the slope portion 115 and the flange portion 118.

As shown in FIGS. 5 through 7, various embodiments may be provided according to the bending angle θ. The support rail 110 according to such various embodiments may be formed by bending a sheet metal. According to various embodiments, a bending portion exists between the base portion 111 and the slope portion 115 and between the slope portion 115 and the flange portion 118. By bending the sheet metal having a plate shape, the support rail 110 having any of the shapes shown in FIGS. 5 through 7 may be formed. By bending the sheet metal having a plate shape a plurality of times, the support rail 110 may be obtained. Accordingly, a special process, such as extrusion molding, is not required to obtain a complex cross-sectional shape.

According to various embodiments, the base portion 111, the slope portion 115, and the flange portion 118 of the support rail 110 may be connected to each other such that an end of one portion is connected to an end of another portion. For example, the base portion 111, the slope portion 115, and the flange portion 118 of the support rail 110 may be connected in the stated order, wherein one end of the base portion 111 and one end of the slope portion 115 are connected to each other, and the other end of the slope portion 115 and one end of the flange portion 118 are connected to each other. As such, the support rail 110 may be a single layer, for example, a single sheet metal layer, as the base portion 111, the slope portion 115, and the flange portion 118 are connected to each other.

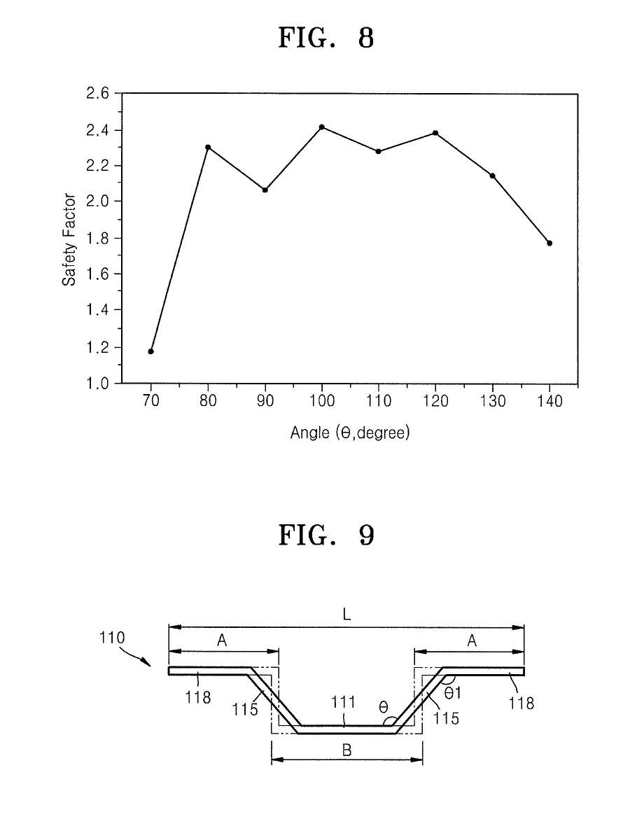

FIG. 8 illustrates a graph showing a safety factor according to the bending angle θ of the support rail 110. In FIG. 8, results of calculating safety factors while variously changing the bending angle θ of the support rail 110 from 70° to 140° are shown. Here, the safety factors are calculated assuming a snow load applying a uniform pressure of 5400 Pa on a surface of the photoelectric panel 10.

The safety factor is related to a breaking strength of a substrate glass forming the photoelectric panel 10, and is a value at which the substrate glass is expected not to break, and thus, denotes a safety margin for preventing breaking. A design standard for a safety factor may vary, but it is assumed that a sufficient safety factor is obtained when a safety factor is equal to or higher than 2.1.

For reference, the substrate glass of the photoelectric panel 10 may be weaker than the support rail 110 to a shock or an external force. Accordingly, the support rail 110 may be designed based on the safety factor of the photoelectric panel 10.

As shown in FIG. 8, when the bending angle θ of the support rail 110 is between 80° to 120°, the safety factor equal to or higher than 2.1 may be obtained. The safety factor is remarkably low when the bending angle θ is lower than 80°. The safety factor also becomes remarkably lower when the bending angle θ is higher than 130°. In particular, the safety factor drops below 2.0 when the bending angle θ is 140° or higher. For example, when the bending angle θ of the support rail 110 is lower than 80° or higher than 130°, a distance between the front and the back occupied by a cross section of the support rail 110 is decreased, and thus the inertia moment is decreased. Accordingly, for example, a resistance characteristic with respect to bending during a snow load of about 5400 Pa may be weakened. Referring to FIG. 6, when the bending angle θ is lower than 80°, the distance between the front and back occupied by the cross section of the support rail 110 is decreased. Also, referring to FIG. 5, when the bending angle θ is higher than 130°, the distance between the front and back occupied by the cross section of the support rail 110 is also decreased.

Referring to FIG. 8, high safety factors are obtained when the bending angle θ is from about 95° to about 105°, and a highest safety factor is obtained when the bending angle θ of the support rail 110 is 100°. As a result, the bending angle θ may be set to 80°≦θ≦130°, or, for example, 95°≦θ≦105°. By obtaining a sufficient safety factor, the support rail 110 may be prevented from breaking despite of the weight of the photoelectric panel 10, and the snow load or wind load applied by the environment.

For reference, in FIG. 8, the safety factor is calculated by variously changing the bending angle θ while maintaining a fixed length L of the support rail 110, the fixed length L of the support rail 110 being a distance between outer ends of the flange portions 118 (see FIG. 9). Accordingly, contact area between the support rail 110 and the photoelectric panel 10 varies according to the bending angle to maintain the fixed length L.

FIG. 9 illustrates how to calculate a safety factor by varying the value of the bending angle. Referring to FIG. 9, the base portion 111 and the flange portion 118 are connected to the joining portion 115. As an original state in the calculation, the joining portion 115 may meet both the base portion 111 and the flange portion 118 at an angle of 90 degrees. From this original state, bending portion 111 may be slanted to predetermined angles between the joining portion 215 and the base portion 111 and flange portion 118 while maintaining the fixed length L of the support rail 110. In the current embodiment, a computation analysis may be performed as described above in order to calculate the safety factor according to the change of the bending angle θ.

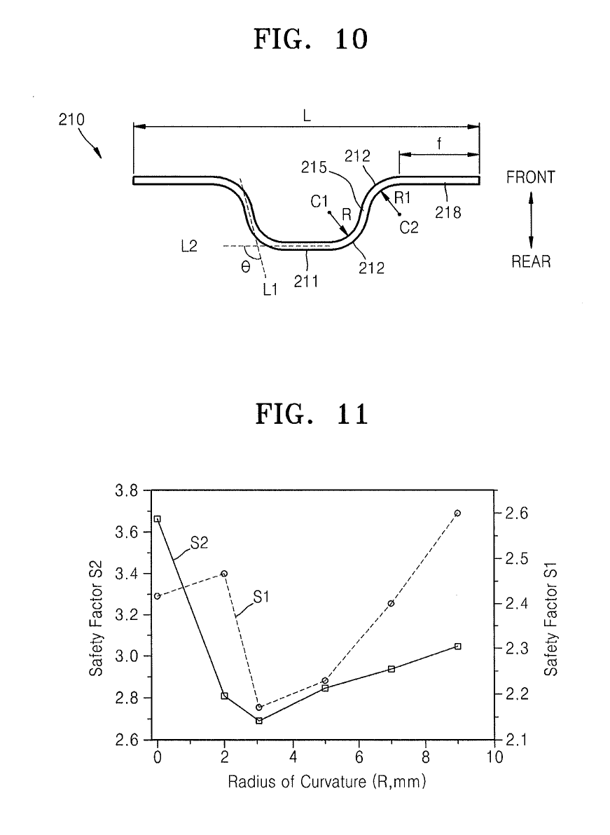

FIG. 10 illustrates a view showing a cross-sectional shape of a support rail 210, according to another embodiment. Referring to FIG. 10, the support rail 210 includes a base portion 211, a flange portion 218 protruding forward at two sides of the base portion 211, and a slope portion 215 inclining to connect a stepped portion between the base portion 211 and the flange portion 218. In the current embodiment, a round portion 212 is formed on a boundary between the base portion 211 and the slope portion 215 and on a boundary between the slope portion 215 and the flange portion 218. For example, the round portion 212 may smoothly connect sharp corners forming a singular point so as to prevent stress concentration and a negligent accident caused by carelessness.

A round degree of the round portion 212 may be determined based on radii of curvature R and R1 from centers of curvature C1 and C2. The radii of curvature R and R1 of the round portion 212 may provide a design variable of the support rail 210.

The round portion 212 may be formed on at least any one of a corner between the base portion 211 and the slope portion 215, and a corner between the slope portion 215 and the flange portion 218. For example, referring to FIG. 10, the round portion 212 may be formed on both of the corners between the base portion 211 and the slope portion 215 and between the slope portion 215 and the flange portion 218 while having different centers of curvatures C1 and C2 and different radii of curvatures R and R1.

As shown in FIG. 10, the round portions 212 having the same shape, i.e., the same centers of curvatures C1 and C2 and the same radii of curvatures R and R1 may be formed on the corners between the base portion 211 and the slope portion 215 and between the slope portion 215 and the flange portion 218. Round portions 212 having the same shape may be formed to promote process convenience.

For reference, hereinafter, the term “radius of curvature R of the round portion 212” may denote both the radius of curvature R of the round portion 212 between the base portion 211 and the slope portion 215 and/or the radius of curvature R1 of the round portion 212 between the slope portion 215 and the flange portion 218.

As shown in FIG. 10, the base portion 211 and the slope portion 215 contact each other at the bending angle θ. The bending angle θ may be defined to be an angle formed by an extending line L2 of the base portion 211 and an extending line L1 of the slope portion 215. Since the bending angle θ has been described above, details thereof are not repeated here.

FIG. 11 illustrates a graph showing a safety factor of the support rail 210 according to the radius of curvature R of the round portion 212. Referring to FIG. 10, the safety factor is calculated by variously changing the radius of curvature R of the round portion 212 from 0 mm to 9 mm while maintaining the bending angle θ of the support rail 210 to 100°. In FIG. 11, the safety factor is calculated by assuming a snow load applying a uniform pressure of 5400 Pa to the surface of the photoelectric panel 10.

In FIG. 11, a safety factor S1 is related to a breaking strength of the substrate glass forming the photoelectric panel 10, and is a value in which the substrate glass is expected not to break, and thus, denotes a safety margin for preventing breaking. A design standard for a safety factor may vary, but it is assumed that a sufficient safety factor is obtained when a safety factor is equal to or higher than 2.1. A safety factor S2 is related to a breaking strength of the support rail 210, and denotes a safety margin for preventing breaking.

The safety factors S1 and S2 may both provide design conditions of the support rail 210. The support rail 210 may be designed based on the substrate glass, which may be relatively weaker than the support rail 210. The safety factor S1 may have priority over the safety factor S2, and hereinafter, when a particular safety factor is mentioned, the safety factor may denote the safety factor S1.

Referring to FIG. 11, when the radius of curvature R of the round portion 212 is 3 mm, the safety factors S1 and S2 are the lowest. Also, when the radius of curvature R increases or decreases from 3 mm, the safety factors S1 and S2 are increased. For example, when the radius of curvature R is between 2.5 mm to 4 mm, the safety factors S1 and S2 are the lowest or close to the lowest. Accordingly, the radius of curvature R of the round portion 212 may be set to either 0 mm≦R≦2.5 mm or 4 mm≦R≦9 mm to avoid the above range. The safety factors S1 and S2 equal to or higher than 2.1 are obtained even when the radius of curvature R of the round portion 212 is 3 mm when the bending angle θ is set to 100° to obtain a highest safety factor with respect to the bending angle (refer to FIG. 8). However, the radius of curvature R of the round portion 212 may be set to avoid about 3 mm to obtain a higher safety factor under the same condition.

When the radius of curvature R is 0 mm, the round portion 212 is not formed. When the radius of curvature R is 0 mm, the safety factor S2 is maximum, but the safety factor S1 of the substrate glass, which is relatively weak, is not relatively high. For example, the safety factor S1 tends to decrease as the radius of curvature R is decreased from 2 mm to 0 mm. Accordingly, 0 mm may be avoided as the radius of curvature R.

FIG. 12 illustrates a graph showing a safety factor of the support rail 210 according to a ratio of a radius of curvature R of a round portion to a length L of the support rail 210. Referring to FIG. 12, the horizontal axis indicates a normalized scale of a relative ratio of the radius R of curvature to the length L of the support rail 210, expressed as R/L (%). In the present instance, the length L of the support rail 220 was fixed at 91.6576 mm. Accordingly, the optimum ranges of 0 mm<R≦2.5 mm and 4 mm≦R≦9 mm may be expressed as 0 (%)<R/L≦2.728 (%) and 4.364 (%)≦R/L≦9.819 (%). Moreover, the ratio of the radius of curvature R of a round portion to a length L of the support rail 210 may be used to define the optimum ranges with respect to the safety factors S1, S2 when the length L varies from the 91.6576 mm value provided as an example.

For reference, in FIGS. 11 and 12, the safety factors S1 and S2 are calculated by variously changing the radius of curvature R while maintaining a fixed length L of the support rail 210, the fixed length L of the support rail 210 being a distance between outer ends of the flange portions 218.

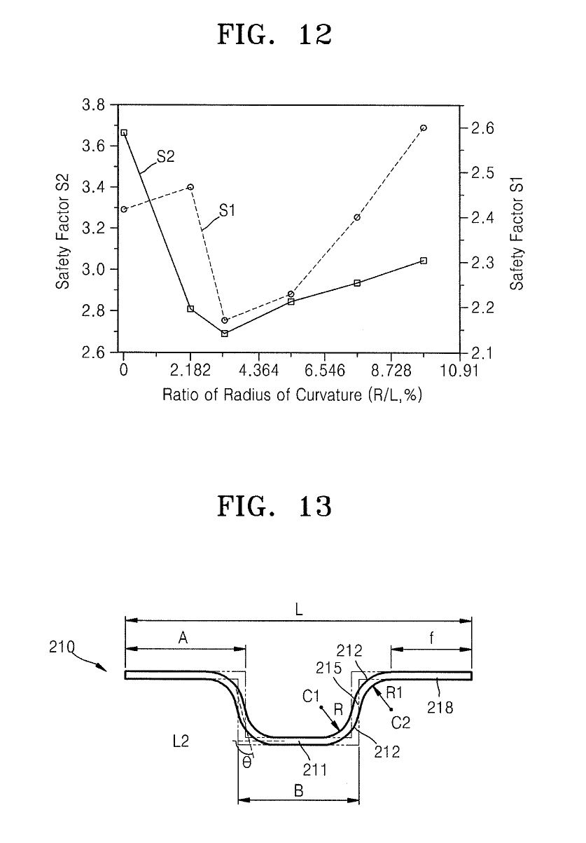

FIG. 13 illustrates how to calculate a safety factor by varying the value of the radius of curvature R, R1, and hence, the value of the ratio of a radius of curvature R of a round portion to a length L of the support rail 210. Referring to FIG. 13, the base portion 211 and the flange portion 218 are connected to the joining portion 2215. As an original state in the calculation, the joining portion 215 may meet both the base portion 211 and the flange portion 218 at radius of curvature of 0. From this original state, various radii of curvature between the joining portion 215 and the base portion 211 and flange portion 218 may be provided while maintaining the fixed length L of the support rail 210. In the current embodiment, a computation analysis is performed as described above in order to calculate the safety factor according to the change of the radius of curvature and the ratio of the radius of curvature to the length L of the support rail 210.

In FIG. 11 or 12, the upper limit may be determined as R=9 mm (R/L=9.819%), considering a shrinkage of the length f of the flange portion resulting from the variation of the radius of curvature while maintaining a constant length L of the support rail 210. Beyond the upper limit, the length f of the flange portion may become too short to stably support the photoelectric panel 10. Also, the length B of the base portion 211 may become too short so as to limit the coupling area of the base portion 211, which may cause a weakness in the coupling strength between the base portion 211 and the photoelectric panel 10.

The weight of the support rail 210 according to the radius of curvature R is calculated according to Table 1 below. As shown in Table 1, when the radius of curvature R is 0 mm, the weight of the support rail 210 is heaviest. Considering structural rigidity and production costs of the photoelectric panel assembly, the radius of curvature R may avoid 0 mm.

TABLE 1

| Radius of Curvature (mm) | Weight (kg) of Support Rail |
|---|---|
| 9 | 0.400 |
| 7 | 0.408 |
| 5 | 0.416 |
| 3 | 0.424 |
| 2 | 0.428 |
| 0 | 0.440 |

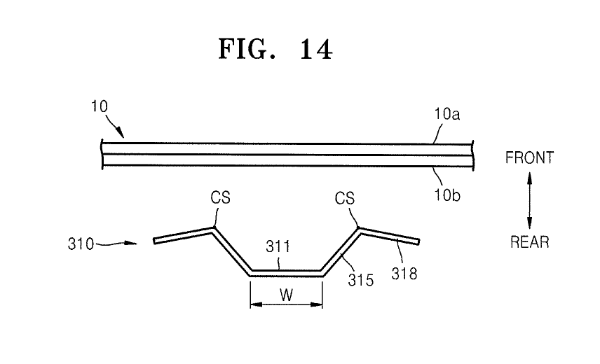

FIG. 14 illustrates a view for describing a case when a sheet metal is excessively bent while forming a support rail 310. As shown in FIG. 14, when the support rail 310 is formed by bending the sheet metal, the sheet metal may be excessively bent. Also, when the radius of curvature is 0 mm, i.e., when a round portion is not formed, a sharp corner CS may be formed between a base portion 311 and a slope portion 315 or between a slope portion 315 and a flange portion 318, and at this time, a stress may be concentrated on the photoelectric panel 10. Accordingly, the radius of curvature R may be set to 0 mm<R≦2.5 mm or 4 mm≦R≦9 mm, excluding 0 mm. In other implementations, the ratio of the radius of curvature R to a length L of the support rail may be 0 (%)<R/L≦2.728 (%) and 4.364 (%)≦R/L≦9.819 (%).

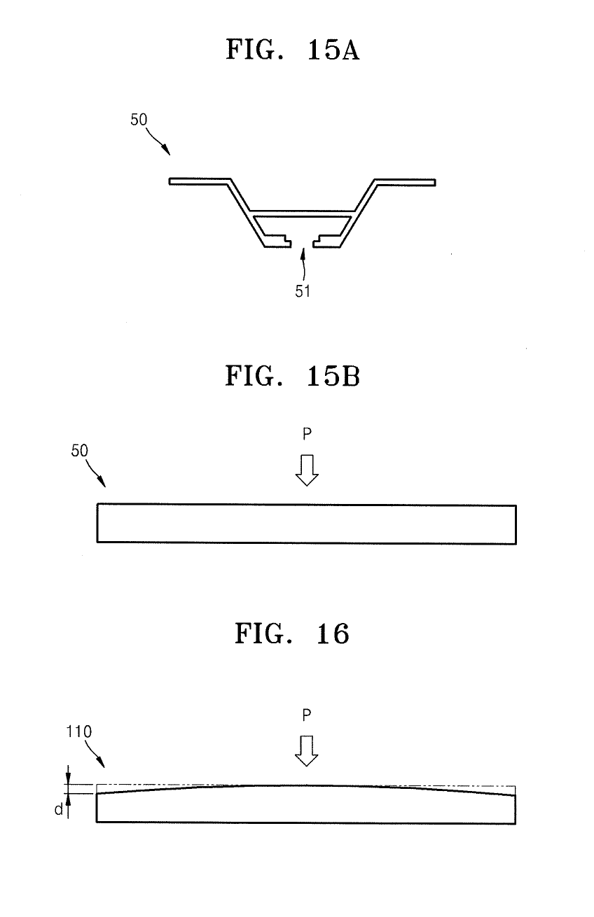

FIGS. 15A and 15B illustrate views showing a support rail 50 according to a comparative example. In detail, FIG. 15A illustrates a view showing a cross-sectional shape of the support rail 50 and FIG. 15B illustrates a view showing a side shape of the support rail 50.

Referring to FIG. 15A, a base portion 51 of the support rail 50 may have a double structure. Rigidity of the support rail 50 may be strengthened via the base portion 51 having the double structure, but the support rail 50 that barely bends to have a flat structure may cause a strong contact pressure with respect to the photoelectric panel 10.

FIGS. 15B and 16 illustrate views showing deformed states of the support rail 50 and 110, respectively according to the comparative example and to an embodiment.

As shown in FIG. 12B, the support rail 50 according to the comparative example barely bends despite of the weight of the photoelectric panel 10, and maintains an approximately flat shape. In this case, the photoelectric panel 10 bends due to its weight and contacts ends of the support rail 50, and thus a strong contact pressure may be applied to some parts of the photoelectric panel 10. As a result, the photoelectric panel 10 may be damaged if only the rigidity of the support rail 50 is considered.

As shown in FIG. 16, the support rail 110 according to the embodiment elastically bends due to the weight of the photoelectric panel 10 by a bending amount d. A contact pressure applied to the photoelectric panel 10, i.e., a contact pressure applied to the photoelectric panel 10 when end portions of the support rail 110 contact the photoelectric panel 10, is remarkably low compared to that of the comparative example. Accordingly, by elastically deforming the support rail 110, the photoelectric panel 10 may be prevented from being damaged due to the contact pressure of the support rail 110.

For reference, referring to FIG. 2, when the end portions of the support rail 110 pressurize and contact the rear surface 10b of the photoelectric panel 10, maximum stress regions ms are formed in the rear surface 10b of the photoelectric panel 10. In the current embodiment, by elastically deforming the support rail 110, the photoelectric panel 10 may be prevented from being damaged due to the contact pressure of the support rail 110.

As shown in FIG. 5, the support rail 110 may be formed by bending the sheet metal, and thus may be a single layer of the sheet metal in which the base portion 111, the slope portion 115, and the flange portion 118 are connected to each other. The support rail 110 may be easily elastically deformed, since it is formed in a single layer, and may be easily formed by simply bending the sheet metal. However, according to the comparative support rail 50 of FIG. 15A, the base portion 51 has a double structure, and the support rail 50 may be difficult to form via a simple process, for example, by bending a sheet metal, but instead is formed via a complex process, such as extrusion molding.

In detail, based on the cross-sectional shape of the support rail 50 of FIG. 15A, it is determined that it is difficult to form the support rail 50 via simple bending but instead, the support rail 50 must be formed via extrusion molding. For example, when the support rail 50 is divided into three portions, the support rail 50 is not a single layer in which an end of a portion is connected to an end of another portion, and the base portion 51 has the double structure. Such a shape of the support rail 50 may not be formed by simply bending a sheet metal, but instead is formed via a high price molding process, such as extrusion molding.

By way of summation and review, one or more embodiments include a photoelectric panel assembly that is conveniently manufactured and is capable of preventing a stress from being intensively applied to a photoelectric panel and preventing the photoelectric panel from being damaged, via a shape design of a support rail for mounting the photoelectric panel thereon.

According to one or more embodiments, by optimizing a shape of a support rail supporting a photoelectric panel by being mounted on a rear surface of the photoelectric panel, a stress concentration locally applied to the photoelectric panel may be reduced and the photoelectric panel may be prevented from being damaged by using the support rail.

According to one or more embodiments, since a support rail is formed by bending a sheet metal, the support rail is easily manufactured without having to perform a special process, such as extrusion molding, to form a complex cross-sectional structure, and is manufactured at a relatively low cost.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. A photoelectric panel assembly, comprising:
a photoelectric panel;
a support rail coupled to a rear surface of the photoelectric panel, the support rail including:
a base portion parallel to and spaced apart from the photoelectric panel;
flange portions parallel to and adhered to the photoelectric panel;
slope portions between the base portion and respective ones of the flange portions; and
rounded portions between the base portion and the slope portions and between the slope portions and the flange portions.

2. The photoelectric panel assembly as claimed in claim 1, wherein a bending angle between the base portion and each of the slope portions and between each of the slope portions and each of the flange portions is between about 80° and about 130°.

3. The photoelectric panel assembly as claimed in claim 1, wherein a bending angle between the base portion and each of the slope portions and between each of the slope portions and each of the flange portions is between about 95° and about 105°.

4. The photoelectric panel assembly as claimed in claim 1, wherein a bending angle between the base portion and each of the slope portions and between each of the slope portions and each of the flange portions is about 100°.

5. The photoelectric panel assembly as claimed in claim 1, wherein a ratio of a radius of curvature of the rounded portions between the base portion and the slope portions and the rounded portions between the slope portions and the flange portions relative to a length of the support rail is greater than zero (%) and less than or equal to 2.728 (%), the length of the support rail being a distance between outer ends of the flange portions.

6. The photoelectric panel assembly as claimed in claim 1, wherein a ratio of a radius of curvature of the rounded portions between the base portion and the slope portions and the rounded portions between the slope portions and the flange portions relative to a length of the support rail, is greater than or equal to 4.364 (%) and less than or equal to 9.819 (%), the length of the support rail being a distance between outer ends of the flange portions.

7. The photoelectric panel assembly as claimed in claim 1, further including an adhesion layer between the flange portions and the photoelectric panel.

8. The photoelectric panel assembly as claimed in claim 1, wherein the support rail extends in a first direction and further including a mount rail extending in a second direction different from the first direction, the mount rail being connected to the base portion of the support rail.

9. The photoelectric panel assembly as claimed in claim 8, wherein the mount rail is connected to the base portion of the support rail through a bracket that is attached to a surface of the base portion facing away from the photoelectric panel.

10. The photoelectric panel assembly as claimed in claim 1, wherein the support rail is elongated in a first direction.

11. The photoelectric panel assembly as claimed in claim 10, wherein a length of the support rail in the first direction is less than a length of the photoelectric panel in the first direction.

12. The photoelectric panel assembly as claimed in claim 10, wherein a length of the support rail in the first direction is less than half a length of the photoelectric panel in the first direction.

13. A photoelectric panel assembly, comprising:
a photoelectric panel; and
a plurality of support rails coupled to a rear surface of the photoelectric panel, each support rail including:
a base portion parallel to and spaced apart from the photoelectric panel;
flange portions parallel to and adhered to the photoelectric panel; and
slope portions, between the base portion and respective ones of the flange portions;
wherein,
each of the support rails is elongated in a first direction, a length of each of the support rails in the first direction being less than half a length of the photoelectric panel in the first direction, and
the support rails are spaced apart from each other in the first direction and in a second direction perpendicular to the first direction so as to be symmetrically arranged with respect to a center of the photoelectric panel.

14. The photoelectric panel assembly as claimed in claim 13, wherein the plurality of support rails are four in number, each of the support rails being centered in a respective quadrant of the photoelectric panel.

15. The photoelectric panel assembly as claimed in claim 13, wherein, with respect to each of the support rails, a bending angle between the base portion and each of the slope portions and between each of the slope portions and each of the flange portions is between about 80° and about 130°.

16. The photoelectric panel assembly as claimed in claim 13, wherein, a bending angle between the base portion and each of the slope portions, and between each of the slope portions, and each of the flange portions is between about 95° and about 105°.

17. The photoelectric panel assembly as claimed in claim 13, wherein a bending angle between the base portion and each of the slope portions, and between each of the slope portions, and each of the flange portions is about 100°.

18. The photoelectric panel assembly as claimed in claim 13, wherein each of the support rails includes rounded portions between the base portion and the slope portions and between the slope portions and the flange portions.

19. The photoelectric panel assembly as claimed in claim 18, wherein a ratio of a radius of curvature of the rounded portions between the base portion and the slope portions and a ratio of a radius of curvature of the rounded portions between the slope portions and the flange portions relative to a length of each support rail is greater than 0 (%) and less than or equal to 2.728 (%), the length of each support rail being a distance between outer ends of the flange portions.

20. The photoelectric panel assembly as claimed in claim 18, wherein a ratio of a radius of curvature of the rounded portions between the base portion and the slope portions and the rounded portions between the slope portions and the flange portions relative to a length of each support rail is greater than or equal to 4.364 (%) mm and less than or equal to 9.819 (%) mm, the length of each support rail being a distance between outer ends of the flange portions.
